(19) United States
(12) Patent Application Publication
(10) Pub. No.: US 2024/0295616 A1
(43) Pub. Date: Sep. 5, 2024

(54) MAGNETO-OPTIC MAGNETOMETER

(71) Applicant: Arizona Board of Regents on Behalf of the University of Arizona, Tucson, AZ (US)

(72) Inventors: Sasaan Showghi, Tucson, AZ (US); Shelbi Jenkins, Tucson, AZ (US)

(21) Appl. No.: 18/712,428

(22) PCT Filed: Nov. 22, 2022
(86) PCT No.: PCT/US2022/080359

§ 371 Date: May 22, 2024

Related U.S. Application Data
(60) Provisional application No. 63/264,456, filed on Nov. 23, 2021.

(51) Int. Cl. G01R 33/032; G01R 1/067; G01R 15/24

(52) U.S. Cl. CPC G01R 33/0322; G01R 1/06755; G01R 15/246; G01R 15/247

(57) ABSTRACT

Methods, devices and systems are described that can be used to measure small magnetic fields, such as nano-Tesla and sub nano-Tesla magnetic fields. An example magnetometer includes a core having a photonic material that receives and maintains the propagation of polarized light. The magnetometer's cladding includes a polymer-based magneto-optic (MO) material in contact with the core which surrounds at least part of the core. The core and the cladding are configured to allow at least a portion of the polarized light to enter the cladding to interact with the polymer-based MO material in presence of an external magnetic field. Measurements of the light's polarization state after interaction with the polymer-based magneto-optic (MO) material enable a determination of a strength of the magnetic field.

### CROSS-REFERENCE TO RELATED APPLICATIONS

This application claims priority to the provisional application with Ser. No. 63/264,456, titled “Magneto-Optic Magnetometer,” filed Nov. 23, 2021. The entire contents of the above noted provisional application are incorporated by reference as part of the disclosure of this document.

### TECHNICAL FIELD

The disclosed technology relates to devices and methods for measuring magnetic fields.

### BACKGROUND

A magneto-optic magnetometer by way of on-chip resonators or tapered waveguides can be used in various applications, including biomedical fields, for measuring magnetic fields, such as those used in compact biomedical systems such as brain-mapping magnetoencephalography (MEG) imaging techniques. Additional applications include their use for telecommunications and environmental sensing. For example, current GPS devices rely on RF signals that are highly susceptible to interference, thus magnetic field sensors can offer alternatives that are not easily interfered or altered when compared to their RF counterparts. It is therefore beneficial to develop magnetometers that are low cost and can make high sensitivity measurements.

### SUMMARY

The disclosed embodiments relate to Photonic Integrated Circuit (PIC) based magnetometers that can be used to measure small magnetic fields, such as nano- and sub nano-tesla magnetic fields. High sensitivity magneto optic nanocomposite materials are employed as optical device cladding and/or device materials to register shifted polarization due to Faraday rotation. Devices based on evanescent field interaction may include ring, disc, racetrack, or whispering-gallery resonators, on-chip adiabatic tapers or low index contrast waveguide/clad configurations. Devices based on nanocomposite waveguides or devices may be fabricated directly from patterned nanocomposite films to achieve sub-micro tesla level detection.

Using differential detection and evanescent fields that interact with magneto-optic materials on a photonic chip in accordance with the disclosed embodiments, magnetic fields well below the limitations of the surrounding earth's magnetic field, as well as other urban magnetic fields, can be measured. Example devices utilize on-chip resonators and tapered fibers with magneto-optic nanocomposite polymers as a top cladding material. The Faraday effect that occurs when the light interacts with a magneto-optic polymer in the presence of a magnetic field allows the changes in the light's polarization state to be measured, which can then be traced back to determine the strength and orientation of the present magnetic field.

One example of magnetometer comprises a core comprising a photonic material, where the core is configured to receive polarized light and maintain propagation of the polarized light that traverses therethrough. The magnetometer also includes a cladding that comprises a polymer-based magneto-optic (MO) material that is in contact with the core and surrounds at least part of the core. The core and the cladding are configured to allow at least a portion of the polarized light to enter the cladding to interact with the polymer-based MO material in presence of an external magnetic field. The measurements of the light's polarization state after interaction with the polymer-based magneto-optic (MO) material enable a determination of a strength of the magnetic field.

### BRIEF DESCRIPTION OF THE DRAWINGS

FIG. 1 illustrates an example optical resonator.

FIG. 2 illustrates the magneto-optic Faraday effect and the associated parameter for MO material.

FIG. 3 illustrates representations of right-hand circular (RHC), left-hand circular (LHC) and linear polarizations.

FIG. 4 illustrates examples optical signals in a Mach-Zehnder modulator.

FIG. 5 illustrates examples transmission diagrams for resonator device in on and off states.

FIG. 6 illustrates an example of on and off state of the magneto optic modulator.

FIG. 7 illustrates a group of diagrams showing the change of transmission spectra of the resonator due to a change in the width of a Lorentzian associated with the resonator.

FIG. 8 illustrates an example of relationship between the Lorentzian width and the Q factor.

FIG. 9 illustrates an example of relationship between loss (Kappa) and the Q factor.

FIG. 10 illustrates two example diagrams showing Lorentzians at different widths.

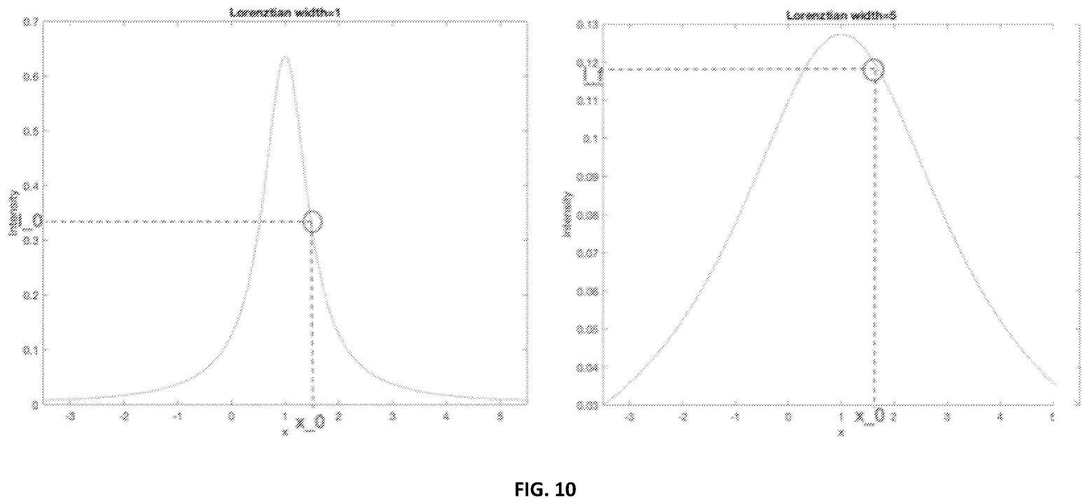

FIG. 11 illustrates an example of the ratio of the reduced and initial intensity as a function of subsequent Lorentzian width size.

FIG. 12 illustrates another example of relationship between loss (Kappa) and the Q factor

FIG. 13 illustrates an example diagram where the magnetic field is directed across the disk resonator in a single orientation.

FIG. 14 illustrates an example of relationship between the rotation of polarization (Theta) and the magnetic field (B).

FIG. 15 illustrates an example of relationship between the magnetic field-induced loss and the magnetic field.

FIG. 16 illustrates an example of relationship between the Q factor and the magnetic field.

FIG. 17 illustrates another example of relationship between loss (Theta) and the magnetic field (B).

FIG. 18 illustrates another example of relationship between the magnetic field-induced loss and the magnetic field.

FIG. 19 illustrates another example of relationship between the Q factor and magnetic field.

FIG. 20 illustrates another example of relationship between loss (Theta) and the magnetic field (B).

FIG. 21 illustrates another example of relationship between the magnetic field-induced loss and the magnetic field.

FIG. 22 illustrates another example of relationship between the Q facor and the magnetic field.

FIG. 23 illustrates an example micro-ring device in which part of the silicon dioxide cladding is replaced with an MO material.

FIG. 24 illustrates simulation results related to cladding thickness with respect to cladding overlap factor.

FIG. 25 illustrates an example of fabrication process of the MO modulator.

FIG. 26 illustrates an example schematic of a setup for conducting magnetic response measurements.

FIG. 27 illustrates an example plot of extinction ratio of a resonator for different relative wavelength positions.

FIG. 28 illustrates an example device that may be implemented as part of various disclosed devices.

FIG. 29 illustrates an example configuration of a racetrack resonator.

FIG. 30 illustrates a set of operations that can be carried out to measure a magnetic field using a magnetometer in accordance with an example embodiment.

### DETAILED DESCRIPTION

Atomic vapor magnetometers, MRI Imaging, superconducting quantum interference device (SQUID) sensors, and general magnetometers are currently the leading candidates for highly sensitive magnetometers, but each suffer from various shortcomings and certain disadvantages. For example, on-chip magnetometers have been proposed using two nested microcavities with nonlinear nitrogen vacancy (NV) centers in a diamond waveguide. The absorption of IR light from the NV center is dependent on the magnetic field. This method has demonstrated improved magnetic field sensitivities up to two orders of magnitude as compared to a NV without the nested microcavities. Although these results show promise in the ability to measure magnetic fields on the order of 1 nT with micrometer spatial resolution, this proposed design is costly and complicated in its fabrication necessities. Additionally, the complexities in the fabrication leave these devices vulnerable to low long-term stability.

A proposed optomechanical magnetometer utilizes high quality microtoroid silica resonators with magnetostrictive disk embedded inside. The embedded disk deforms in the presence of an external magnetic field exerting a force on the silico resonator. This force modifies the circumference of the cavity, and this shifts the optical resonance. This method has demonstrated measurement capabilities in the T regime. However, these materials and fabrication methods are exceedingly complex and expensive to fabricate. Additionally, the fragility of microtoroid resonators makes them unsuitable for robust conditions and durable systems. An on-chip superconducting quantum interferences device (SQUID) sensor is another candidate that works by integrating the SQUID sensors and the feedback circuitry directly onto the same chip. The device has high sensitivity but the intricate and sensitive fabrication of these devices as well as their significant temperature dependence and their inability to operate above cryogenic temperatures reduces the viability of using these devices in portable and compact systems. Thus, the high-cost, fragility, and complex fabrication of the aforementioned devices make them unsuitable for durable and portable systems for environmental and biomedical applications.

Active integrated silicon photonic devices have been instrumental the advancement of data processing and communications for decades. Fabricating active photonic devices is costly and often involves complex processing methods. The prevalence of magneto-optic (MO) devices in optical systems has been essential to the growth and development of the telecommunication sector, as well as sensing systems for biomedical and environmental applications. The viability of using MO devices in various systems is dependent on their performance, cost, and physical dimensions. Integrating MO materials with on-chip photonic devices for fully integrated systems is the subject of active on-going research.

The disclosed embodiments address the above shortcomings of existing systems, and rely on integrating MO materials with silicon photonic devices, which among other features and benefits, provide low-cost and durable magnetometers that can be produced using simple fabrication techniques while enabling the measurement of very small magnetic fields in the range of, for example, nano Tesla. Additionally, the disclosed magnetometers are versatile for numerous applications and system integrations due in-part to the ability to tune the sensitivity and physical dimensions of the devices.

One example device is formed by depositing a polymer-based MO material onto a bare, high-Q ring resonator. The long path length offered by the high-Q resonator combined with the high magnetic field response from the MO material creates a device capable of detecting the presence of external magnetic fields. This response is demonstrated by a change in the output signal from the device when the wavelength is positioned on resonance. A change in the external magnetic field reduces the Q factor of the device, resulting in higher optical output when the device is configured that it is coupled with a single bus waveguide. In device configurations that the measurement is performed from a second drop port waveguide, and a change in the external magnetic field decreases the Q factor resulting in a lower optical output. That is, if there is a second bus waveguide the Q factor still decreases with an external field, but the change in output power will be reduced because it will be on a resonance peak instead of a resonance dip. In one specific example, by integrating high-Verdet polymer materials onto a Si₃N₄ resonant structure, the MO response can be optimized through longer effective interaction lengths and the Q factor of the resonator can be manipulated with an external magnetic field.

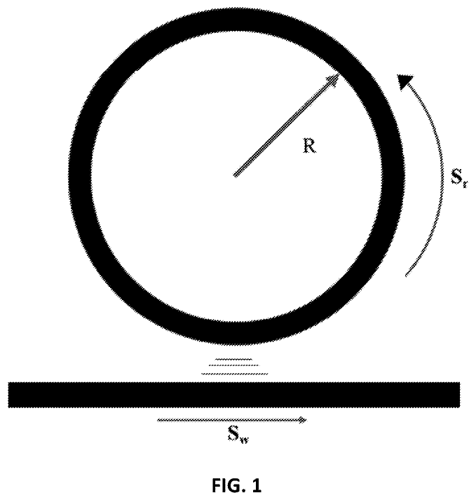

By the way of example and not by limitation, in the sections that follow the basics of an optical resonator is described to facilitate the understanding of the underlying concepts. An optical resonator is a cavity in which light can form a standing wave. There are many types of geometries that function as optical resonators. To facilitate the description, ring and disk resonators are discussed as working examples in this patent document. As show in FIG. 1, light is coupled into the resonator via a waveguide commonly referred to as the through port. As light propagates along a waveguide, there exists an evanescent field just outside of the waveguide core. In FIG. 1 evanescent fields from a waveguide generated by the wave Sw couple into the resonator with radius R, and propagate along the circumference as Sr. Typically, this evanescent field is inconsequential on its own, but these fields allow us to couple light into a resonant structure. The evanescent wave holds energy that can be transferred into a ring resonator or another optical device such as a directional coupler.

Once the energy is coupled into the resonator, it can propagate in the resonator's waveguide structures. As with a simple waveguide design, the light is totally internally reflected off the interfaces as it travels along the circumference of the resonator. The light will continue along this path until it is radiated out or evanescently coupled back into the bus waveguide by the same mechanism it was coupled in. Alternatively, a second waveguide could serve as a drop port for the light to couple out of, rather than back into the bus waveguide. By the nature of a resonator, only select wavelengths can couple into and propagate inside the resonant structure. In order to form standing waves, only wavelengths that are integer multiples of the round trip optical path length of the resonator will be supported. These supported wavelengths are given by the following equation:

$$n {λ}_{n} = 2 π R$$

In this equation, n is a positive integer, R is the radius of the ring, and the λ is the wavelength. All other wavelengths will not form standing modes and will instead destructively interfere within the waveguide and not contribute to the build up of energy within the cavity. Quality factor of the resonator, or simply the Q factor is a parameter that is used to indicate the energy loss within the resonator. For an optical ring resonator, the Q factor is defined as the energy stored in the resonator per optical cycle, divided by power coupled or scattered out of the resonator per optical cycle. For typical resonators, this dimensionless parameter is often on the order of 10³ or 10⁴. For high quality resonators however, the Q factor can reach as high as the millions or even billions. In terms of parameters of the resonator system, the Q factor is defined as:

$$Q = \frac{2 {π}^{2} {Rn}_{e}}{{λ}_{0} {κ}^{2}} .$$

In the above equations, R is the radius of the resonator, nₑ is the effective index of refraction of the resonator determined by its guide materials and dimensions, substrate and cladding materials and the operating wavelength, λ₀ is the resonant wavelength, and κ is the coupling constant defined as the fraction of power that is coupled out of the ring due to coupling to the bus and waveguide losses. It is evident that the Q factor is inversely proportional to the coupling constant of the device, which can be broadly defined to describe the loss of the resonator system, whether that be from the light coupling out of the ring, radiation loss, or absorption of light by the device materials. From this we can deduce that by altering the materials to absorb more or less light in the device, we can affect the spectrum of the resonator determined by the Q factor.

Whether or not a mode is supported by a waveguide, and subsequently a resonator structure, is also dependent on the polarization of the light. For any given system, it is likely that the system will better support either TE or TM polarization modes, depending on the design and materials of the devices. For these cases, the polarization can be tuned to optimize the performance of the waveguides as well as the resonator structures. Additionally, if the polarization of the light changes along the path of the device, it can introduce losses to the system reducing the overall output, and the Q factor of the resonator.

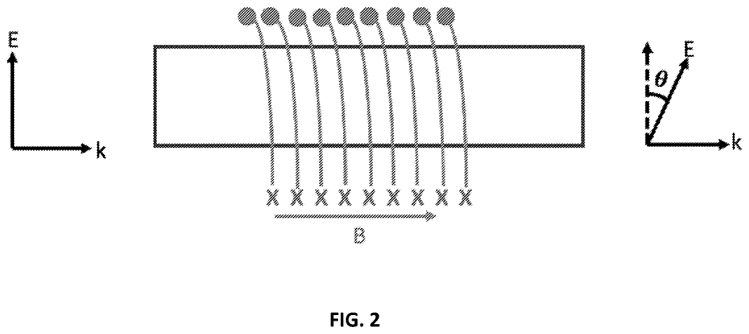

To further facilitate the understanding of the disclosed technology, it is beneficial to describe the Faraday effect and the associated parameters for MO material as provided below. The magneto-optic Faraday effect, otherwise known as magnetic circular birefringence (MCB), is the rotation of the polarization of linearly polarized light in a medium in the presence of a magnetic field. This is demonstrated below in FIG. 2. In order to better understand the mechanisms behind this phenomenon, one must first understand the principles of light polarization, dielectric tensors, and indices of refraction.

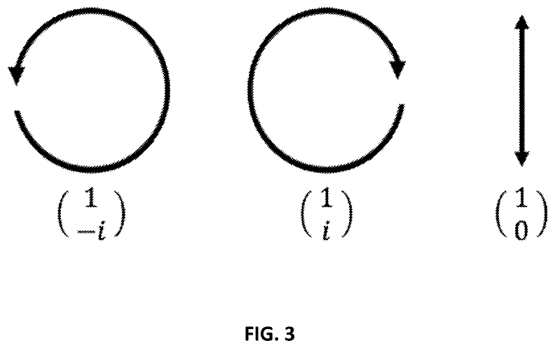

Light is radiation that takes the form of an electromagnetic wave. The electric and magnetic field components oscillate perpendicular to each other in space. There are many parameters used to describe these waves, such as the amplitude or frequency of oscillation, the direction of propagation defined by the k-vector, and the polarization. The parameter most relevant to understanding the Faraday effect is the polarization. The polarization of light is defined as the oscillation orientation of the electric field component of an electromagnetic wave. These oscillations are typically described as linear, right-hand circular (RHC), left-hand circular (LHC), elliptically polarized, or unpolarized. For the purposes of this discussion, we will only focus on the linear, RHC and LHC definitions which are represented below in FIG. 3. These polarization states can be expressed as their own respective Jones vectors as follows:

$$RHC = \frac{1}{\sqrt{2}} ( \begin{matrix}1 \\ - i\end{matrix} ) , LHC = \frac{1}{\sqrt{2}} ( \begin{matrix}1 \\ i\end{matrix} ) , Linear = \frac{1}{\sqrt{2}} ( \begin{matrix}1 \\ 0\end{matrix} ) .$$

The Faraday effect describes the rotation of linear polarization in a medium that results from applying an external magnetic field to the system that is either parallel or anti-parallel to the direction of propagation of the light. Linearly polarized light can be deconstructed and written as a superposition of RHC and LHC polarized light, as we can see from the Jones vectors in the above equation. When the electric field is oscillating in a circular direction, we know from Maxwell's equations that this will induce a magnetic field either parallel or anti-parallel to the plane of propagation based on the right-hand-rule. When the linearly polarized light passes through a medium where a magnetic field is present, the external magnetic field will either enhance or diminish the initial magnetic field of the two polarizations. This combination of magnetic fields induces a change in the index of refraction with which the two respective polarization states interact. This equal but opposite change in index induces a phase difference between the two polarization states that translates to a rotation of linear polarization when the RHC and LHC polarizations are superimposed. This process can be more thoroughly understood by considering the effects of magnetic fields on the dielectric tensor of a medium. The dielectric tensor is used to describe how electromagnetic radiation and an external magnetic field will interact within a certain medium. The most generalized dielectric tensor takes the following form:

$$ϵ = ( \begin{matrix}{ϵ}_{xx} & {ϵ}_{xy} & {ϵ}_{xz} \\ {ϵ}_{yx} & {ϵ}_{yy} & {ϵ}_{yz} \\ {ϵ}_{zx} & {ϵ}_{zy} & {ϵ}_{zz}\end{matrix} ) .$$

For isotropic media, the diagonal elements will be identical, while the rest of the elements will be zero. The application of an external magnetic field induces off diagonal elements ±ϵ′, so the resulting dielectric tensor in the presence of an external magnetic field along the z-axis is as follows:

$$ϵ = ( \begin{matrix}{ϵ}_{xx} & {ϵ}^{′} & 0 \\ - {ϵ}^{′} & {ϵ}_{yy} & 0 \\ 0 & 0 & {ϵ}_{zz}\end{matrix} ) .$$

The induced off-diagonal elements, ±ϵ′, are directly proportional the applied magnetic field and correspond to changes in the refractive index of the material for LHC and RHC polarizations. The complex refractive index (RI) of a material describes how light will pass through a material, if at all. The RI is defined by its real and imaginary components as follows:

$$n = {n}_{ϵ} + i κ .$$

For this definition the real part, n_{ϵ}, describes the velocity of light as it passes through the medium while the imaginary component κ, determines the absorption of light in the medium. The relationship between the off-diagonal tensor elements and the refractive index is represented by:

$${n}^{\pm } = \sqrt{ϵ \pm i {ϵ}^{′}} ,$$

In the above equation, the plus and minus correspond to the RHC and LHC polarizations. The difference in the RI of the two polarizations causes them to propagate at different velocities through the material which induces a phase difference between the two. This phase change is what accounts for the rotation of linear polarization in the material. The total amount of rotation is given by the following equation:

$$Θ = vBd .$$

In the above equation, dis the length of the material interaction the light experiences, B is the magnitude of the external magnetic field applied along the direction of propagation of light and v is the Verdet constant of the material with units of °/Tm. The Verdet constant, which can be positive or negative, is wavelength and temperature dependent and intrinsic to the material in question.

As noted earlier, the disclosed embodiments can be implemented to operate based on magnetic circular birefringence (MCB), where an external magnetic field rotates linear polarization in a medium by changing the respective real part of the RI for right- and left-hand circular polarization in opposite directions. This polarization rotation can induce loss in a polarization dependent device such as an optical resonator. The change in output signal is then used to determine the strength of the magnetic field.

The disclosed embodiments can be implemented in devices that utilize electrooptic effects that either change the real or imaginary components of the refractive index of the EO material. Recall from above that the real and imaginary components of the refractive index correspond to the refraction and absorption of the material. For these reasons, when an applied electric field changes the real part of the RI, this device is classified as an electro-refractive device, and when it affects the imaginary component it is classified as an electro-absorptive device. These changes are typically caused by changing the concentration of free-charges in the silicon, a mechanism known as the plasma dispersion effect. The modulation of an optical signal via EO-induced absorption is simple in that if the absorption increases, the output signal of the device decreases. This mechanism can be used to effectively modulate the signal with high enough extinction ratio to produce binary code to transfer data. Modulation of an optical signal via changes in the refractive index is less straightforward, but still relatively simple. The example configurations for modulation via refractive index changes are Mach-Zehnder and resonators modulators.

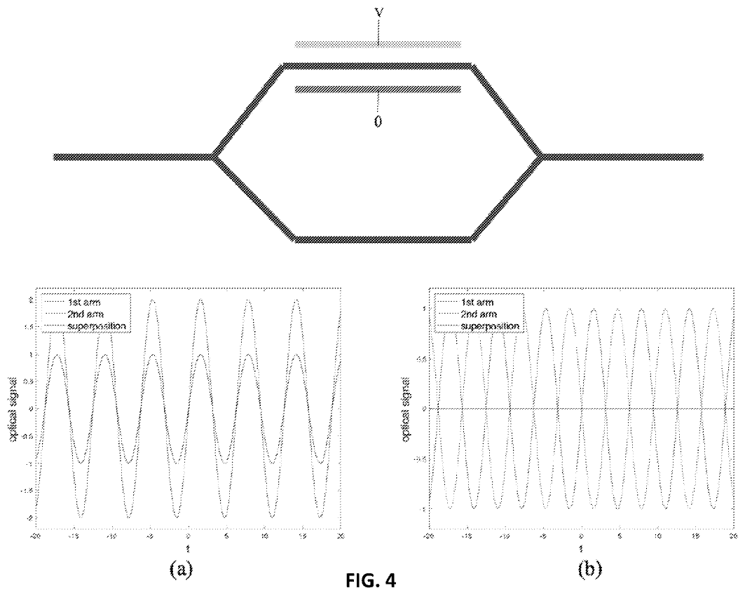

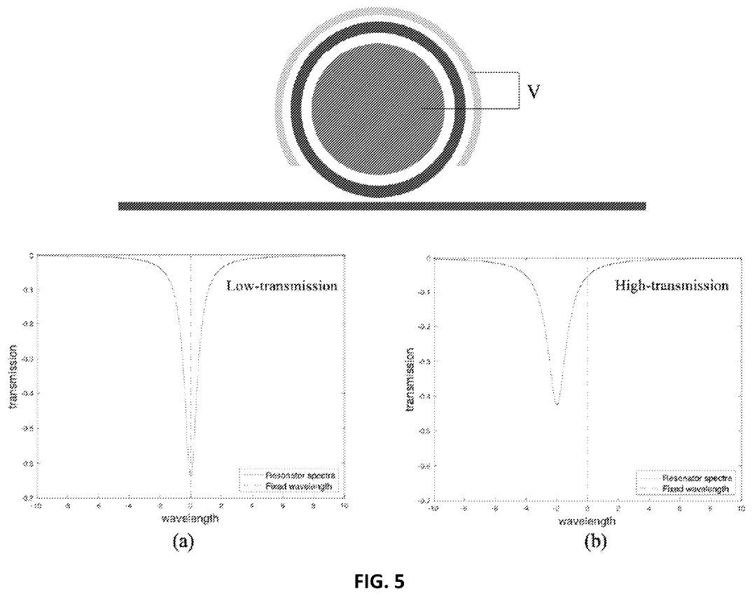

In some configurations, a Mach-Zehnder interferometer can be used to achieve EO modulation by changing the relative phase shift of an optical signal propagating in one arm versus the other such that the two waves destructively interfere when superimposed and diminish the optical output signal. In some configurations, using a resonant structure, the resonant wavelength of the device shifts with a change in the refractive index of the resonator. This allows a shift between an on- and off-resonance states for a given wavelength position. Example Mach-Zehnder (MZ) and resonator device design mechanisms are illustrated in FIGS. 4 and 5, respectively. In particular, panel (a) in FIG. 4 illustrates the optical signals in an MZ electrooptic modulator in an on state, and panel (b) illustrates the optical signal in an off state. Panel (a) in FIG. 5 illustrates the resonator transmission in an off state and panel (b) illustrates the transmission in an on state.

By the way of example and not by limitation, the following sections describe the design of a resonator modulator that integrates magneto-optic polymers with silicon nitride photonic devices. As noted previously, the Faraday effect is the rotation of light polarization in the presence of a magnetic field, and that a change in polarization can change the resonance and Q factor of a resonator. Through use of these two mechanisms, a magneto-optic amplitude modulator can be designed and used for measuring the external magnetic fields. The example device was fabricated using a low-loss silicon nitride micro-ring resonator that include a silicon dioxide cladding. The SiO₂ cladding material was etched away and replaced with a magneto-optic polymer, as will be described later in this patent document. In this way, magneto-optic composites of polymer-coated magnetic nanoparticles were developed. The resonant nature of the device increases the path length of our light interacting with the material, and the MO polymer rotates the light to a polarization state that is not supported by the resonator. This rotation then translates to loss in the device which can be modulated to produce binary signals for telecommunications or can be used to sense the magnetic field external to the device.

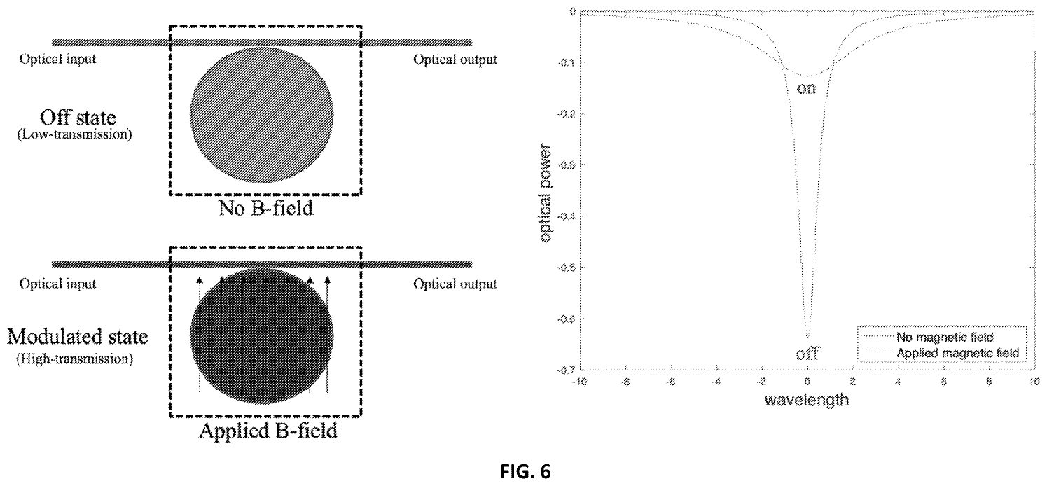

The basic concept of on and off state of the magneto optic modulator is shown in FIG. 6. The resonance spectrum is deep when the modulator is in the off-state and there is no magnetic field applied. When the magnetic field is present, the Q factor is reduced and the transmission at the resonant wavelength increases due to the shortening and broadening of the resonant spectrum.

The performance of this device is dependent on the quality of the resonator, and the materials used. The higher the Q factor of the resonator, the more time the light will spend traveling along the length of the ring. Longer interaction lengths mean greater Faraday rotation, as evident from the above equation for 0. Thus, the contrasts in the modulated signals will be directly related to the resonator quality. Additionally, the materials used for the device greatly affect its performance depending on the refractive indices, absorption and magneto-optic response of the materials. Since the core, cladding and substrate materials directly affect the effective index, and subsequently the mode confinement of a waveguide or resonator, the materials and dimensions can be selected to produce the desired performance by considering various tradeoff. If the materials that offer a high effective index and greater mode confinement are selected, then the mode interaction with the cladding materials will be reduced, resulting in less Faraday rotation and lower extinction capabilities of the modulated signal. However, if the effective index is too low then the mode will not be well-guided and will suffer high loss, especially radiation loss as it propagates along the circumference of the micro-ring. This increase in baseline loss could be enough to reduce the efficacy of the modulator when interacting with a magnetic field.

Most commercially available or easily manufactured waveguides and resonators have either Si or Si₃N₄ core materials. Both of these materials are low-loss for telecom wavelengths, so for this application, the main concern is the material absorption from the cladding. One way to decrease the optical absorption in the cladding material, is to use a polymer-based MO material and increase the particle loadings in the polymer material. Since increasing the particle loading also increases the Verdet constant of the material, these two factors must be balanced to optimize the magneto-optic response of the device as well as the strength of the signal output. In some applications, it may be beneficial to use polymers with high or very high Verdet constants (e.g., between 2×10³ and 2×10⁶). For example, polymer-based materials with cobalt nanoparticles (and polystyrene host polymer) with ultra-high Verdet constant on the order of 10⁵ to 10⁶°/Tm) may be used.

In some applications where high sensitivity of detection is not required, Verdet constants on par with standard garnet materials such and as TGG may be used.

One example device can be constructed as a silicon or silicon nitride micro-disk resonator with a magneto-optic material cladding to operate as an amplitude modulator under the right conditions. The magnetic field interaction with the MO material causes a rotation in the polarization of light in the resonator, increasing the absorption of the system and decreasing the Q factor of the resonator. By determining the relationship between the magnetic field and the change in Q factor, the magnetic field strength can be determined. The transmission spectrum of a disk resonator can be represented as a Lorentzian with a maximum at the resonant wavelength. The Lorentzian equation is given by:

$$L = \frac{1}{π} \frac{1 / 2 Γ}{{( x - {x}_{0} )}^{2} + {( 1 / 2 Γ )}^{2}}$$

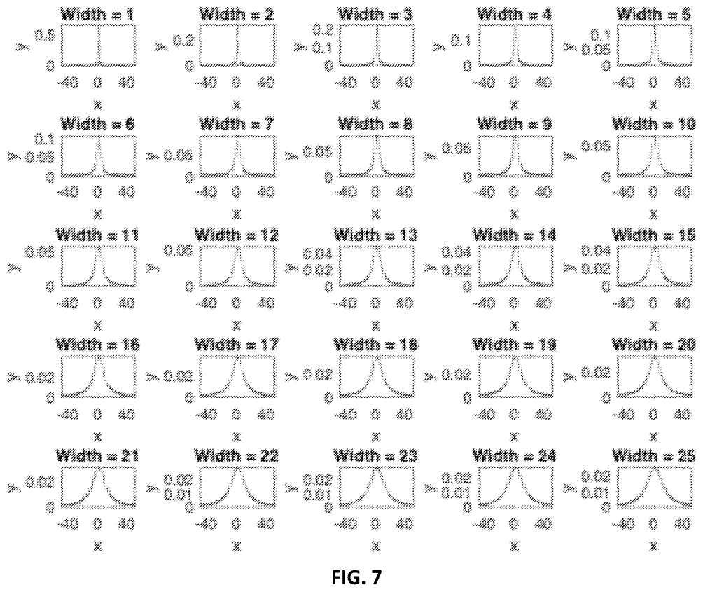

In the above equation, G is the width of the Lorentzian, and x₀ is the resonant wavelength. The resonant wavelength divided by the full width half maximum (FWHM) of the Lorentzian gives the Q factor of the resonator. We have shown how a change in the width affects the transmission spectra of the resonator, as demonstrated below in FIG. 7. For these calculations we assumed an initial width varying from 1 to 25, and a centered wavelength of 1. These values are used for illustration purposes, and can be used as placeholders to show a general relationship trend. Additionally, we calculated Q factor or each Lorentzian, using the following equation:

$$Q = \frac{{λ}_{res}}{{Δλ}_{F W H M}}$$

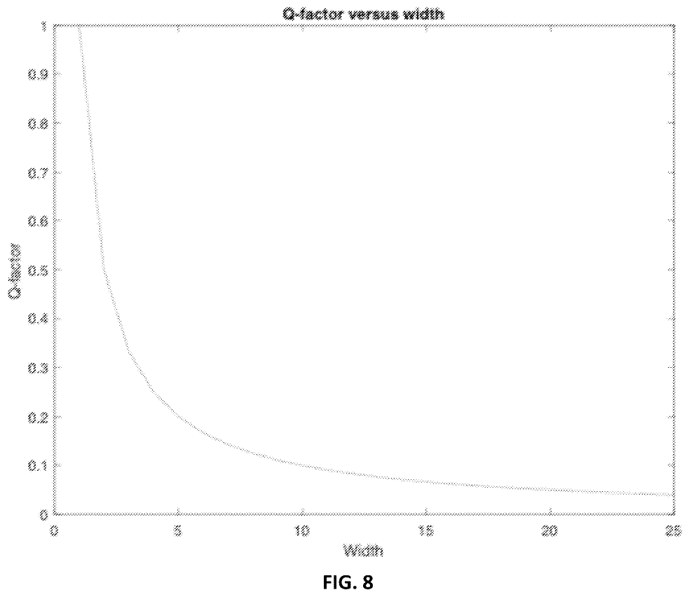

In this equation, where λᵣₑₛ is the resonant wavelength and Δλ_{FWHM} is the full-width half-max of the resonance peak. The relationship between the Lorentzian width and the Q factor is shown in FIG. 8. The next course of action was to characterize the initial loss of our system. To do this, we assumed that the coupling constant of our resonator was proportional to the overall loss in our system, and solved for the coupling constant, κ, as a function of the Q factor using the following equation:

$$Q = \frac{2 π {Rn}_{e}}{{λ}_{0} {κ}^{2}}$$

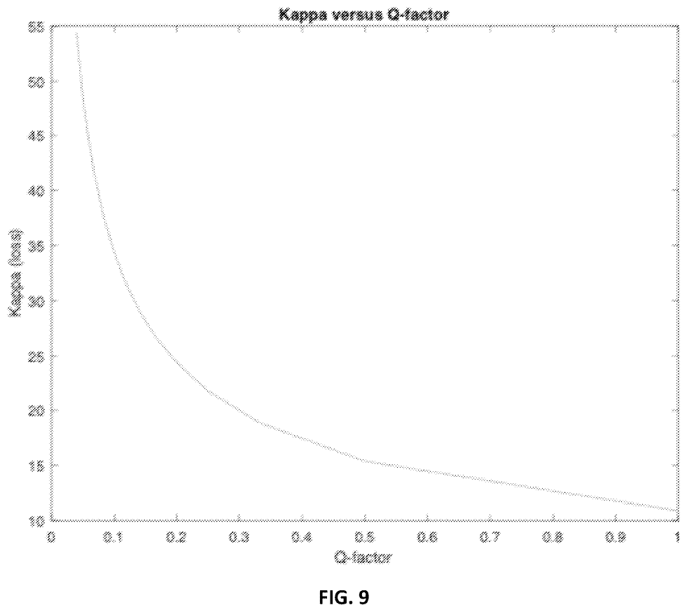

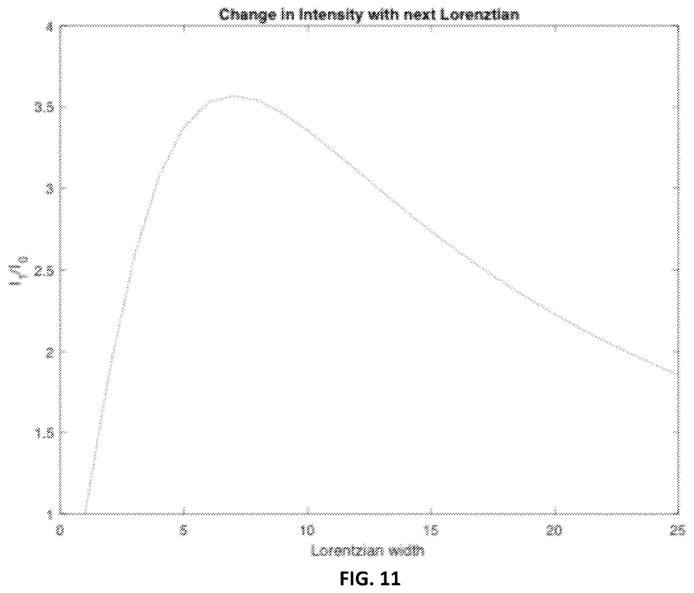

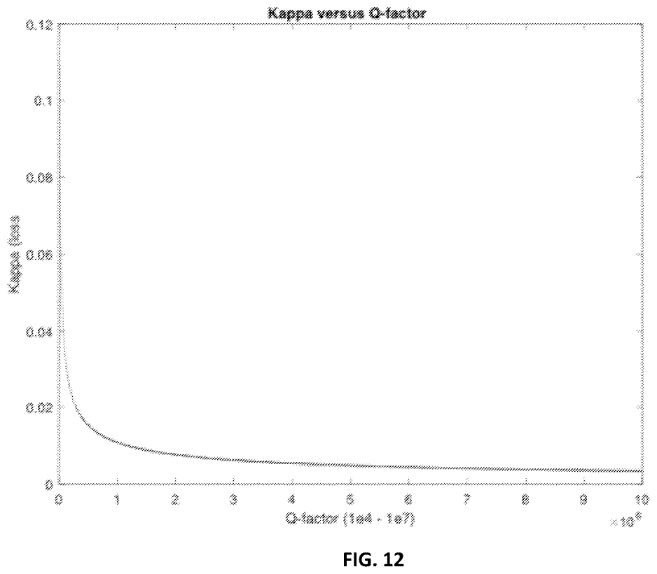

In the above equation, R is the radius of the disk resonator, λ₀ is the resonant wavelength and nₑ is the effective index. With initial values of nₑ=2.9250, λ₀=1550 nm, R=10 μm, and Q ranging from 0.04 to 1, we obtained the relationship depicted in FIG. 9. The values in FIG. 9 are merely used for illustration purposes, and the actual device values are likely higher than those illustrated in FIG. 9. Next, it can be shown how a change in the Q factor of the resonator would change the intensity output of the system. As the Q factor decreases, it is reasonable to assume that the transmission at a resonance wavelength would decrease. To show this, we noted the wavelength and intensity of the rightmost point of the FWHM on the highest Q factor Lorentzian. We then calculated the intensity value at that same wavelength for the next width-size Lorentzian, and so on. This technique is illustrated in FIG. 9, and the ratio of the reduced and initial intensity as a function of subsequent Lorentzian width size is shown in FIG. 11. We can see that there is an optimum relationship between the change in Q factor needed to see a reasonable change in the output intensity of the resonator for a given wavelength. Once we understood the relationship between the Q factor and the output intensity, we then continued to determine these values for systems that can be experimentally measured and compared. By using the same equation used in producing FIG. 9, we solved for κ, assuming real values of a typical silicon resonator of nₑ=2.9250, λ₀=1550 nm, R=10 μm, and Q ranging from 10⁴ to 10⁷. We determined that the loss of the system ranged between 0.1089 and 0.0034 for these values of Q, as shown in FIG. 12.

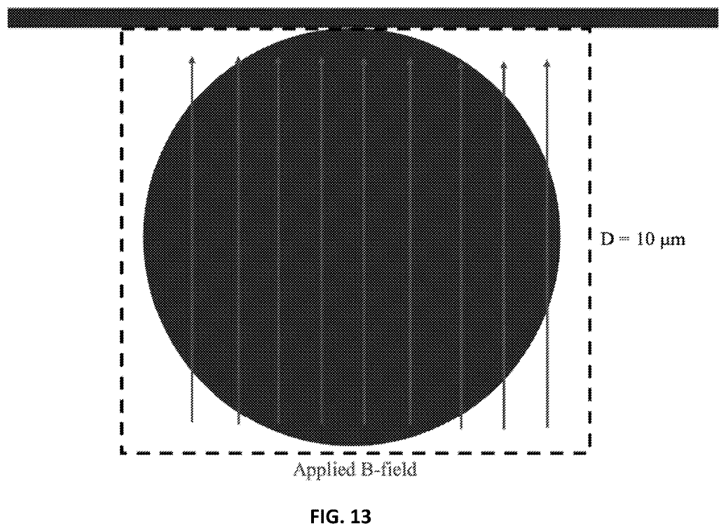

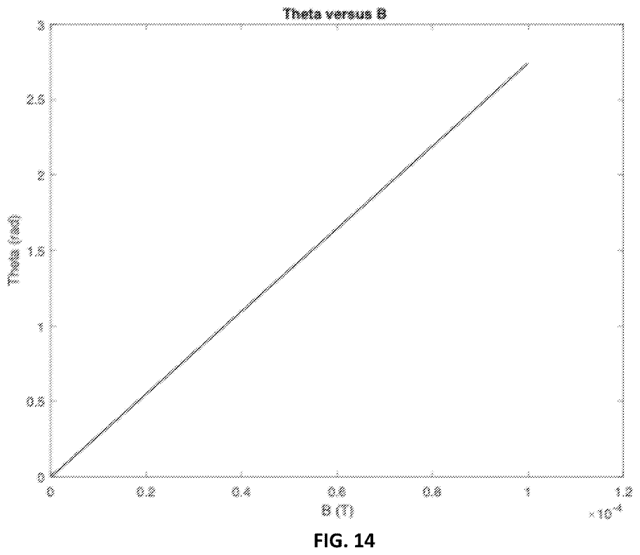

Once the relationship between the Q factor and the initial system loss was obtained, we needed to determine how the magnetic field changes affected the loss, and subsequently the Q factor of a resonator. The next step was to define the relationship between the magnetic field and the polarization rotation of the mode propagating in the resonator. For this we assumed the setup seen in FIG. 13 where the magnetic field was directed across the disk resonator in a single orientation. The Faraday effect stated that the relationship between the magnetic field and angle of polarization rotation is θ=vBd, where v is the Verdet constant of the MO material, d is the interaction length, and B is the magnetic field. We assumed that the interaction length is proportional to the Q factor by the equation d=Q(2R)π. Thus, the rotation of the light polarization can be written as θ=vBQ(2R)π. We assumed example values for radius, R, equal to 10 m, Verdet constant of 8726 rad/Tm, and an initial Q factor of 10⁵. The rotation of polarization as a function of magnetic field within the range of 0 to 0.1 mT is depicted in FIG. 14.

We also used these values, along with a variant of our previous equation, namely,

$${Q}_{0} = \frac{2 π {Rn}_{e}}{{λ}_{0} {κ}_{0}^{2}} ,$$

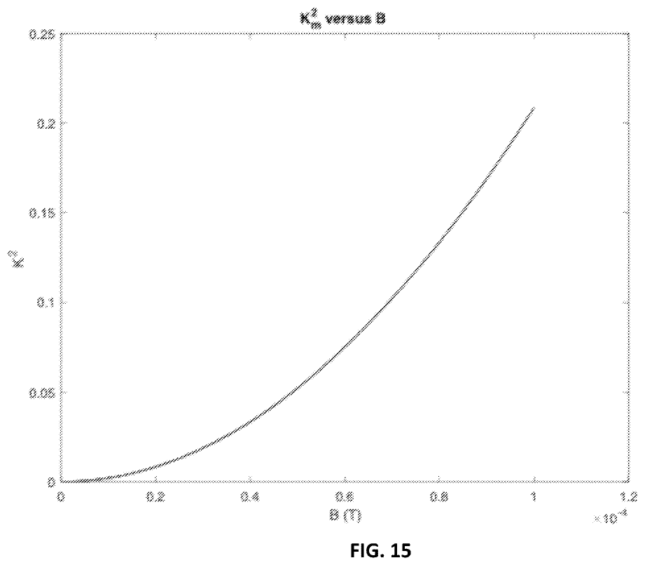

to determine κ₀², or the initial loss of the system. This value was calculated to be 0.0019. To define a relationship between the magnetic field-induced loss, nₘ² and the magnetic field, we used Malus's Law of polarization. We assumed that the loss was proportional to sin² θ. We can see from FIG. 14, that when we are operating within the regime of micro Teslas, as we would be in an ideal case, we can assume a small angle and further approximate κₘ²=θ². Using the Faraday effect relationship describing the angle of rotation, we can write the loss as κₘ²=(vBQ₀(2R)π)². This relationship is shown in FIG. 15.

As the final step, the Q factor of the system is related to the applied magnetic field. We begin with our initial equation relating Q factor and loss:

$$Q = \frac{2 π {Rn}_{e}}{{λ}_{0} {κ}^{2}} .$$

However, we must account for both the initial loss of the system as well the magnetic field induced loss. Thus, we can write the total system loss as κ²=κ₀²+κₘ². Thus, our equation for Q becomes:

$$Q = \frac{2 π {Rn}_{e}}{{λ}_{0} ( {κ}_{0}^{2} + {κ}_{m}^{2} )}$$

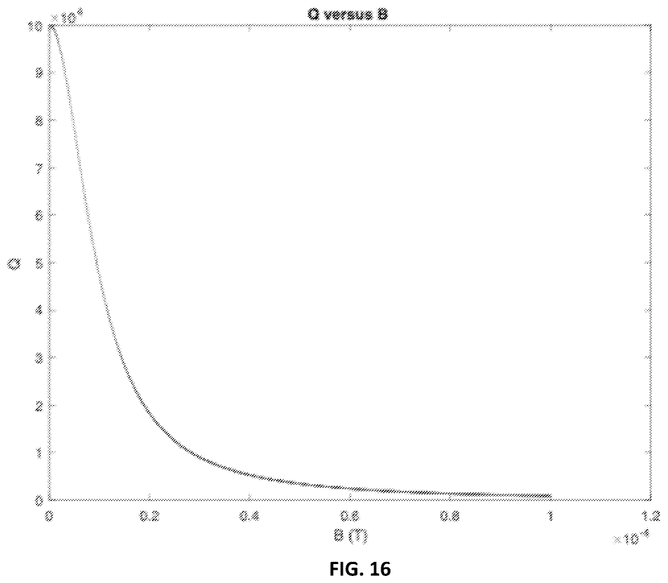

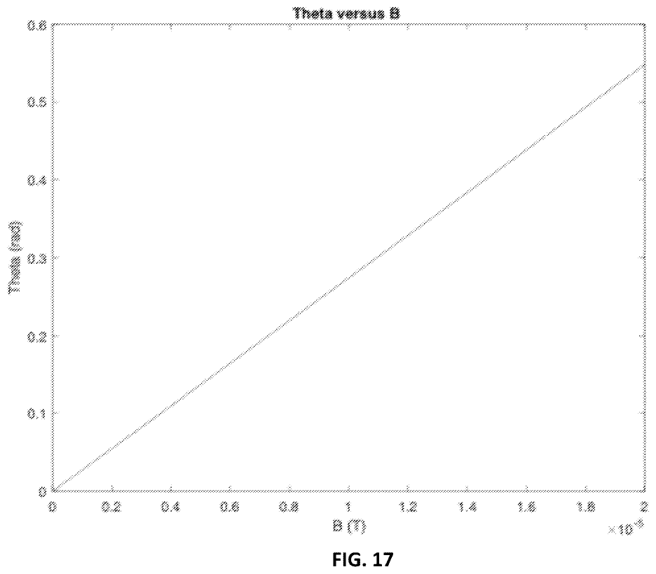

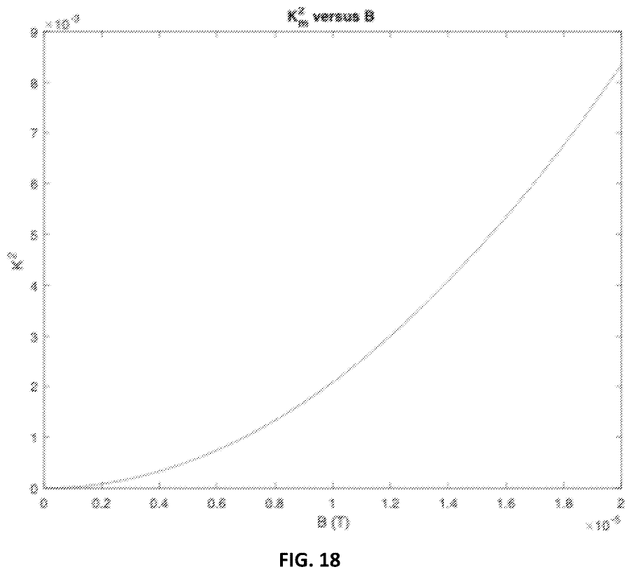

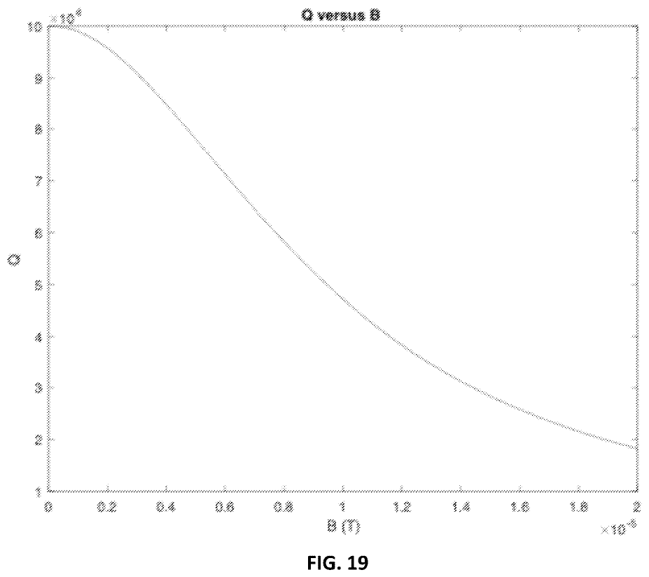

In the above equation, κₘ²=(vBQ₀(2R)π)². FIG. 16 illustrates this relationship between the Q factor of the system as a function of the magnetic field, B. This magnetic field range offers a rotation exceeding 2.5 radians, which is well out of the limit for a small angle approximation. In order to keep our rotation at or below 0.5 radians, we will set an upper limit on the magnetic field to be about 20 μT. The rotation for this field range is illustrated in FIG. 17. From this range we can follow through with the previous analysis and determine our κₘ² and the change in Q factor for this field range. This data is presented in FIGS. 18 and 19, which show κₘ² versus the magnetic field limited to 20 μT and the change in Q factor with respect to a magnetic field up to 20 μT, respectively.

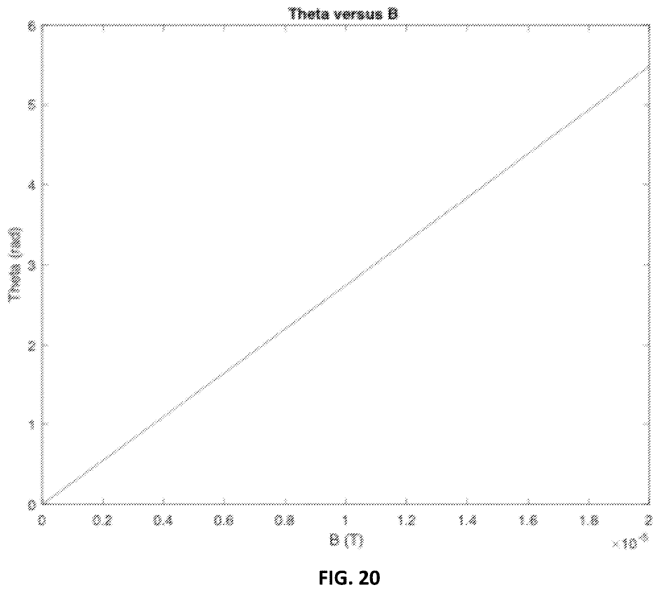

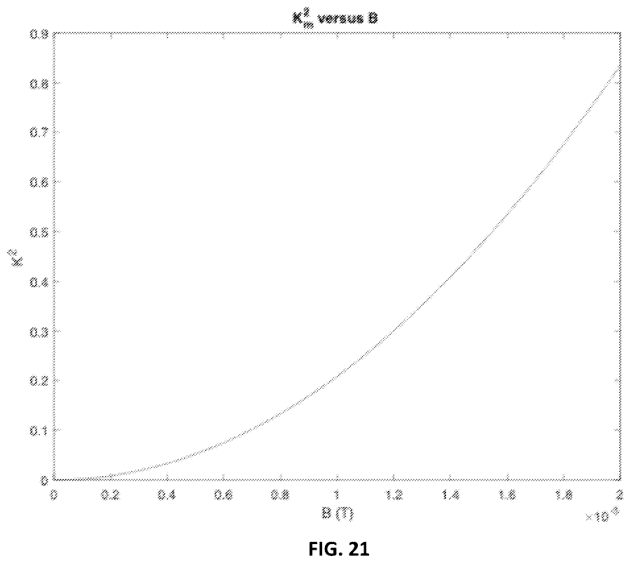

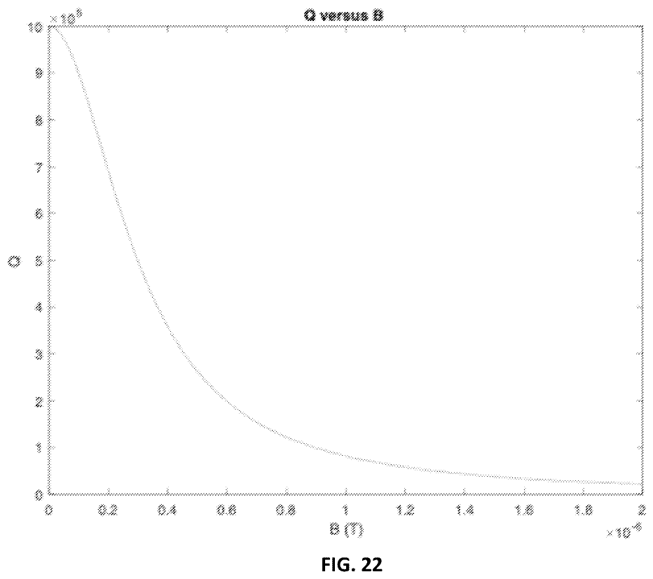

With use of FIGS. 9 and 11, we can see that the optimum output intensity ratio comes from a change in Q factor of about 1 order of magnitude. We can see that we have nearly achieved this result in FIG. 19 by applying a very small field. The next step was to see how an increase in the initial Q factor affects the change in Q with magnetic field. We assumed that the initial Q factor was 1 million. The angle rotation with B with an initial Q of 1 million is illustrated in FIG. 20. The value we get for κ₀² with these parameters is 0.000186, which is much lower than our previous value. Previously, within our chosen magnetic field range our two loss values were comparable, but in the scenario κ₀² is an order of magnitude higher than κₘ². Notice that as the initial Q factor is increased, the angle of rotation is also increased. To keep our analysis within the small angle approximation limit we need to further reduce our magnetic field to 2 μT. With this new field range, the relationships for κₘ² and resulting Q factor are shown in FIGS. 21 and 22, respectively. We can see from this data that increasing the Q allows us to achieve higher contrast in Q factor for smaller magnetic fields.

### Device Fabrication Example:

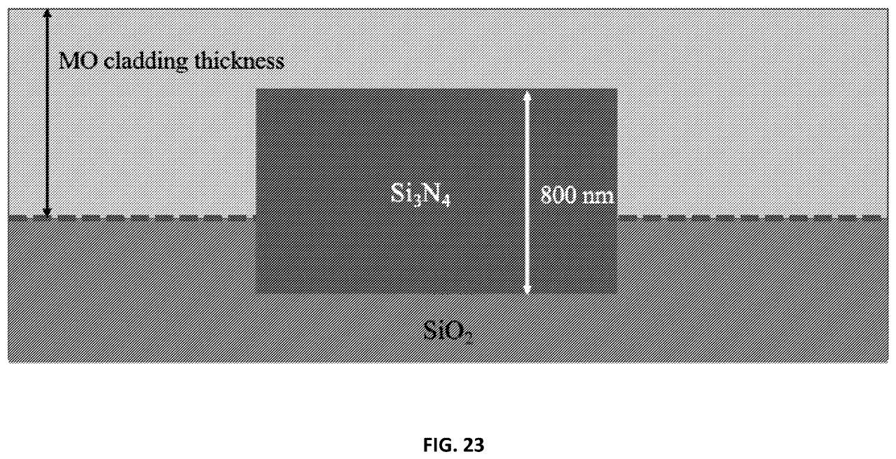

A commercially available micro-ring resonator was purchased. The device has a core material comprising silicon nitride, and a silicon dioxide cladding. At least part of the cladding was removed and replaced with the MO material. FIG. 23 illustrates an example configuration of the device where part of the silicon dioxide cladding is replaced. In its original state, this device had a Q factor of 2.2 million—far greater than we were able to achieve in-house. The high Q factor and nitride material made this device a great candidate for our modulator. High Q factors allow us longer lengths to interact with our magneto-optic materials, and the lower index of Si₃N₄ as opposed to Si decreases the effective index of the device and results in more mode interaction with the cladding materials. Simulations were conducted in FIMMWAVE to show the percentage of mode confinement in the MO cladding material for varying cladding thicknesses. For these simulations we assumed the index of the MO material to be 1.58. The cladding was simulated from 0 to 1300 nm where the increase in thickness corresponds to further etching of the SiO₂ material from the top of the device. Since the Si₃N₄ waveguides and rings are 800 nm, the cladding thickness touches the top of the waveguide at 500 nm. A schematic of the varying cladding thickness with respect to the waveguide structure is shown in FIG. 23.

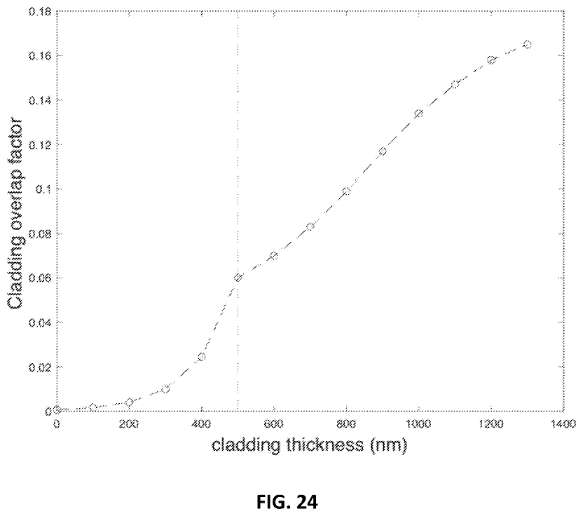

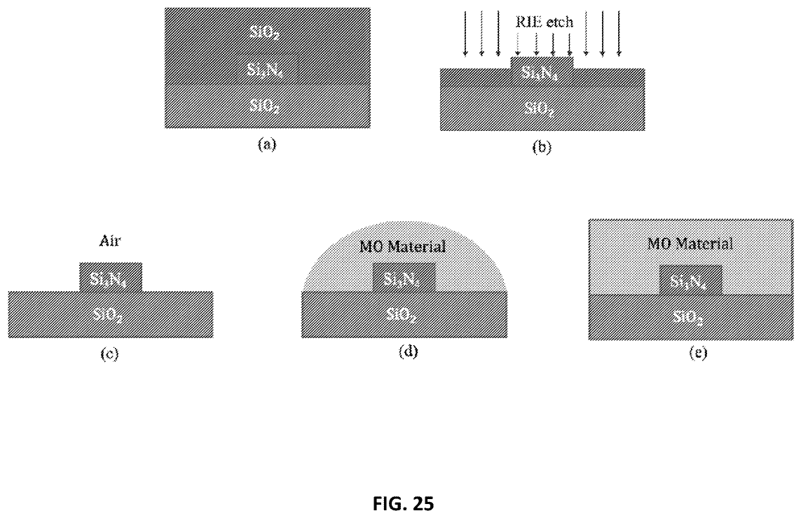

The simulation results in FIG. 24 show that the percentage of mode confinement exponentially increases as the cladding material approaches the top of the waveguide structure, increases more as the SiO₂ sidewalls are reduced and begins to level off as the cladding fully surrounds the waveguide core. This assures us that even without etching past the surface of the waveguide, we can still achieve almost 10% mode interaction with the cladding material. After etching away the initial SiO₂ cladding material using a Plasmatherm Versaline DSE III reactive ion etcher, we were able to deposit the magneto-optic cladding. Through this process we removed enough cladding to expose 100 nm at the top of the nitride resonator to air, which as we have seen from FIG. 24, allows us to assume roughly 7% mode interaction with the cladding material. After removing the top cladding, a layer of our polymer-coated magnetic nanoparticle film was spin coated onto the exposed resonator. The synthesized samples were fabricated with an ink of 2.5 wt % particles loadings of 14 nm cobalt nanoparticles. The film was spun at 1000 rpm for 2 minutes and then dried on a hot plate at 150° C. for four minutes to remove any remaining solvent. The resulting film thickness was 3.5 m. The step-by-step fabrication process is illustrated FIG. 25. In particular panel (a) illustrates the initial state of the chip; in panel (b), the top section of SiO₂ material is removed via reactive ion etching (RIE) to produce the bare core device in panel (c); panel (d) shows deposition of the MO ink; and the final device structure post spin-coating is shown in panel (d). This fabrication method can be tailored to tune the performance of the modulators by choosing a baseline resonator with varying Q factors, changing the etch depth and core exposure of the device, and through material selection.

### Device Characterization Example:

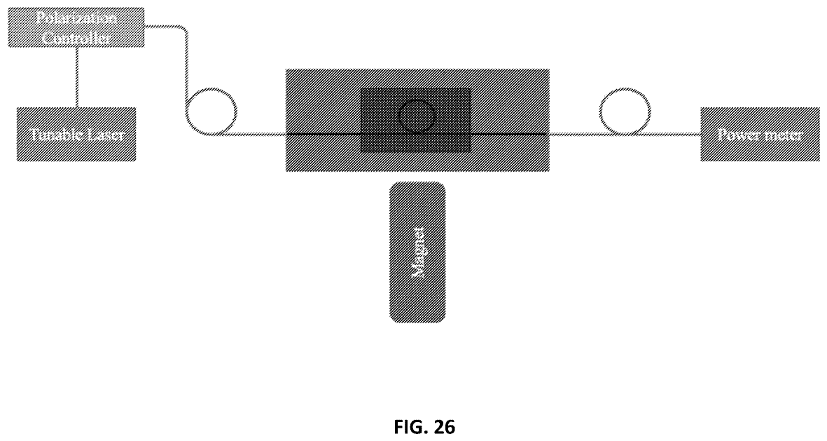

This device was characterized using standard fiber-to-chip-to-fiber butt coupling techniques. An Agilent 8164A tunable laser was guided through a polarization controller and coupled into the bus waveguide of the fully fabricated modulator device. The output signal from the through port of the resonator bus waveguide was coupled into a second optical fiber and connected to a fiber-coupled Newport multi-function optical meter. The Q factor was measured by scanning the tunable laser across the resonance spectrum where the output power was recorded at each wavelength. From this information the resonant wavelength and the FWHM of the resonance was determined. The Q factor was calculated using the equations described earlier. For the magnetic response measurements, the same fiber and chip setup was used connecting the tunable laser to the optical power meter. A 10 mT permanent magnet was oriented along the resonator to elicit the change in output power at different wavelength positions. A schematic of this setup is shown in FIG. 26.

To measure the magneto-optic response, we scanned the tunable laser without an external magnetic field present, until it was positioned on the peak resonant wavelength and measured the output power in dBm (P_{dBm}), which is related to the power in mW (P_{mW}) by the equation:

$${P}_{dBm} = 10 * {log}_{10} ( {P}_{mW} / 1 mW ) .$$

We remeasured the power after applying our external magnetic field. The difference between the two values was taken to be the extinction ratio of the modulator. This measurement was repeated for a wavelength just off-resonance (shifted approximately 0.0002 nm), the FWHM of the resonance, and completely off-resonance. We repeated this measurement for two separate fully fabricated modulators with resonance spectra of varying depth. These results are discussed below.

The extinction ratios (ER) for a high-functioning and a low-functioning modulator device were measured for various wavelength positions in response to a 10 mT static magnetic field. The extinction ratio (ER), otherwise known as the modulation depth, of a modulator is the ratio between the maximum intensity output (Iₘₐₓ) and the minimum intensity output (Iₘᵢₙ) of the modulated signal. This ratio is generally expressed in units of dB via the equation:

$$E R = 10 * {log}_{10} ( {I}_{max} / {I}_{min} ) .$$

The ER measurement results for the two modulators can be seen in Tables 6.1 and 6.2.

TABLE 6.1
ER for the MO modulator using a
low-performance Si₃N₄ resonator.

| λ (nm) | 0 T B-field | 10 mT B-field | ER |
|---|---|---|---|
| 1552.6367 | −14.6 dBm | −12.7 dBm | 1.9 dB |
| 1552.6365 | −13.8 dBm | −12.1 dBm | 1.7 dB |
| 1552.6357 | −10.83 dBm | −9.72 dBm | 1.11 dB |
| 1552.6227 | −5.82 dBm | −5.82 dBm | 0 dB |

TABLE 6.2
ER for the MO modulator using a
high-performance Si₃N₄ resonator.

| λ (nm) | 0 T B-field | 10 mT B-field | ER |
|---|---|---|---|
| 1552.7011 | −24.75 dBm | −20 dBm | 4.75 dB |
| 1552.7009 | −22.24 dBm | −17.84 dBm | 4.4 dB |
| 1552.7004 | −17.58 dBm | −14.9 dBm | 2.68 dB |
| 1552.6974 | −12.09 dBm | −12.08 dBm | 0.01 dB |

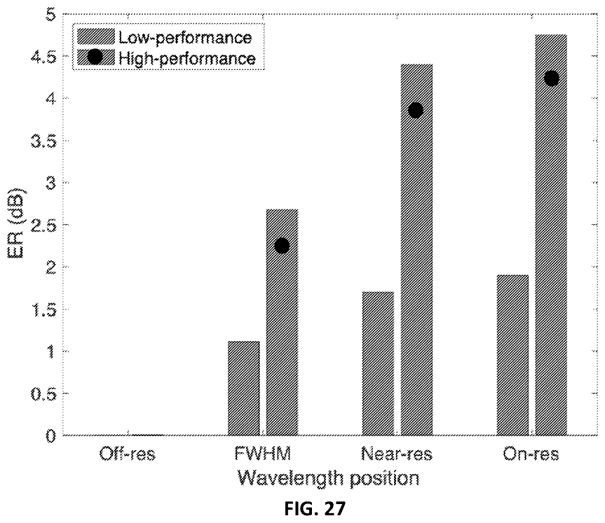

From these results, we have demonstrated an ER up to 4.75 dB with our magneto-optic modulator design. To better depict the ER trend with wavelength position, the ERs are shown in FIG. 27 for the different relative wavelength positions. From this we can see that the ER is reduced as we move the wavelength away from its peak resonance position; this is as we would expect. These results follow the same trend we would expect to see from our prediction of what should happen to the resonator spectra as we introduce an external magnetic field. Consistent with FIG. 6, we expect that the ER when the wavelength is near the peak resonant wavelength to be greater than for wavelengths further from resonance. Both of these modulators successfully demonstrate this behavior. The variance in ER between these two modulators comes from the difference in the baseline output spectra of the resonator. One trade-off that we often see in resonator devices is that in order to achieve a high Q factor, the depth of the resonant spectra must be small. This comes from the coupling constant of our device and the propensity for light to couple in an out of the resonator. Although both resonators showed the same trend with wavelength, we were able to achieve higher ER with the high-performance resonator because the depth of the resonant dip was greater than that of the low-performance modulator. From this contrast we can conclude that our modulator ER performance is dependent and limited by the depth of the device's resonance spectra.

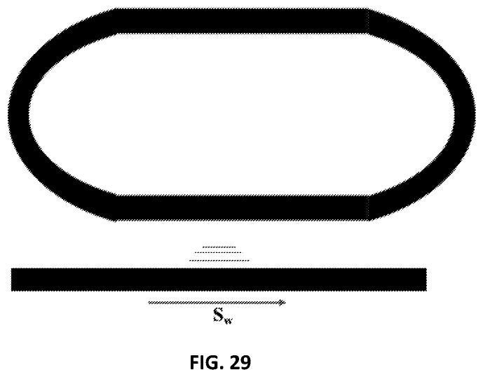

The following is an example method for measuring the external magnetic field using an example magnetometer disclosed herein. (1) The magnetometer, such as a ring or disc magnetometer, is configured to received polarized light and is operable at a resonant frequency in the absence of the external magnetic field. (2) The output light from the resonator is measured using an optical power meter. (3) The wavelength is positioned on resonance where the output power is minimized using, for example, a tunable laser source or by thermal tuning via a temperature stage. (4) An external magnetic field is applied to the resonator and the resulting output power for the on-resonance wavelength position is measured using the optical power meter. (5) The difference between the output power with and without the external magnetic field is calculated. (6) This difference in power is proportional to the external magnetic field. The extent of which can be pre-determined given the resonator dimensions, and the indices and magnetic response of the materials. By knowing this relationship, the strength of or change in the magnetic field can be measured from the change in output signal. In some implementations, a racetrack resonator (an example is shown in FIG. 29), an oval-shaped resonator, or generally a non-circularly symmetric resonator can be used. In such configurations, the magnetic field direction can also be measured by changing the resonator's orientation and noting the change in output power as a function of angular position. For example, the relative orientation of the resonator and the external magnetic field can be changed, and the output power can be measured. This operation can be repeated to improve the detection results. As such, the magnetic fields in specific directions or axis can be measured.

These results demonstrate that we can successfully integrate magneto-optic polymers with silicon (e.g., Si₃N₄) photonic devices with variable performance demonstration. This has been a goal of researchers for more than ten years. The results further demonstrate modulation speeds of at least 1 GHz with low energy per bit rates.

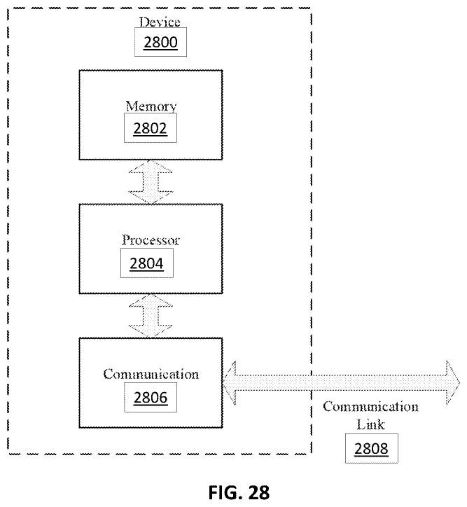

It is understood that the various disclosed embodiments may be implemented individually, or collectively, in devices comprised of various optical components, electronics hardware and/or software modules and components. These devices, for example, may include the device 2800 shown in FIG. 28. The device 2800 can be used to implement at least in-part some of the various disclosed embodiments. The device in FIG. 28 can, for example, be implemented as part of a control system to control the operations of the disclosed light sources, detectors and/or part of the control system that receives and processes the information and electrical signals from the disclosed detectors. The device 2800 comprises at least one processor 2804 and/or controller, at least one memory 2802 unit that is in communication with the processor 2804, and at least one communication unit 2806 that enables the exchange of data and information, directly or indirectly, through the communication link 2808 with other entities, devices, databases and networks. The communication unit 2806 may provide wired and/or wireless communication capabilities in accordance with one or more communication protocols, and therefore it may comprise the proper transmitter/receiver, antennas, circuitry and ports, as well as the encoding/decoding capabilities that may be necessary for proper transmission and/or reception of data and other information. The exemplary device 2800 of FIG. 28 may be integrated as part of any devices or components to carry out any of the disclosed methods.

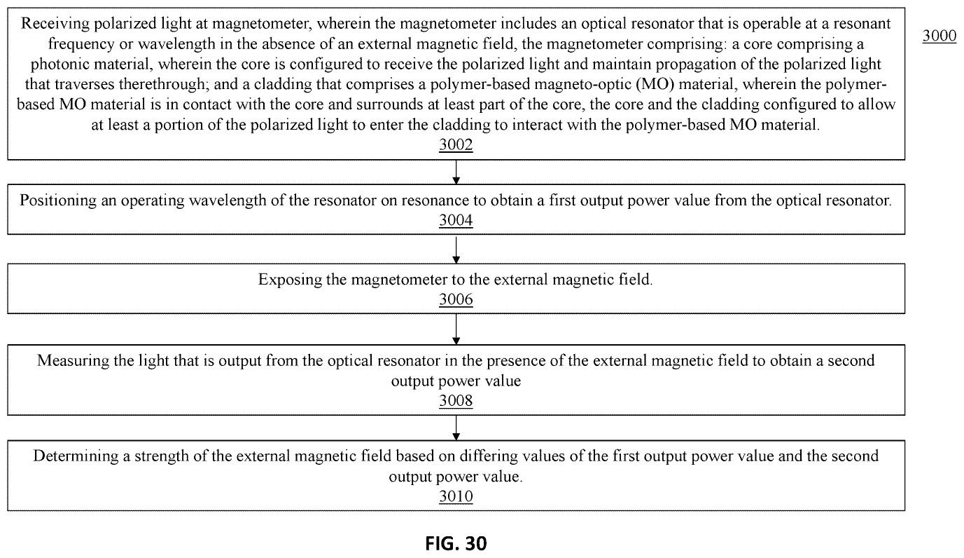

FIG. 30 illustrates a set of operations 3000 that can be carried out for measuring a magnetic field using a magnetometer. At 3002, polarized light is received at the magnetometer. The magnetometer includes an optical resonator that is operable at a resonant frequency or wavelength in the absence of an external magnetic field. The magnetometer comprises a core comprising a photonic material. The core is configured to receive the polarized light and maintain propagation of the polarized light that traverses therethrough; and a cladding that comprises a polymer-based magneto-optic (MO) material. The polymer-based MO material is in contact with the core and surrounds at least part of the core, the core and the cladding configured to allow at least a portion of the polarized light to enter the cladding to interact with the polymer-based MO material. At 3004, an operating wavelength of the resonator on resonance is positioned to obtain a first output power value from the optical resonator. At 3006, the magnetometer is exposed to the external magnetic field. At 3008, the light that is output from the optical resonator in the presence of the external magnetic field is measured to obtain a second output power value. At 3010, a strength of the external magnetic field is determined based on differing values of the first output power value and the second output power value.

In one example embodiment, the strength of the external magnetic field is proportional to a difference in the first output power value and the second output power value. In another example embodiment, positioning the operating wavelength of the resonator on resonance is associated with obtaining a measured output power value from the optical resonator in the absence of the external magnetic field that is minimized. According to another example embodiment, the optical resonator is one of a ring or a disc resonator.

In one example embodiment, the optical resonator is non-circularly symmetric, and the above method further comprises: changing a relative orientation of the optical resonator and the external magnetic field; measuring light that is output from the optical resonator in the presence of the external magnetic field to obtain a third output power value; and determining a direction of the external magnetic field based on at least the second and the third output power value.

In one example embodiment, the direction of the external magnetic field is determined as function of an angular position of the optical resonator in the present of the external magnetic field. In another example embodiment, the magnetometer is part of an integrated photonic chip. In yet another embodiment, a detection sensitivity of the magnetometer to the external magnetic field is based on one or more of: a Verdet constant of the polymer-based MO material, dimensions of the core, dimensions of the cladding or a quality factor of the optical.

Another aspect of the disclosed embodiments relates to a magnetometer that includes a core comprising a photonic material, wherein the core is configured to receive polarized light and maintain propagation of the polarized light that traverses therethrough. The magnetometer further includes a cladding that comprises a polymer-based magneto-optic (MO) material, wherein the polymer-based MO material is in contact with the core and surrounds at least part of the core, the core and the cladding configured to allow at least a portion of the polarized light to enter the cladding to interact with the polymer-based MO material in presence of an external magnetic field, and wherein measurements of a the light's polarization state after interaction with the polymer-based magneto-optic (MO) material enable a determination of a strength of the magnetic field.

In one example embodiment, the core in the above magnetometer comprises a silicon-based material. For example, the core can comprise silicon nitride (Si₃N₄). In another embodiment, the polymer-based MO material has a Verdet constant in the range 2×10³ and 2×10⁶. In another example embodiment, the above magnetometer is implemented as part of an integrated photonic chip. In another embodiment, the above magnetometer is configured as a resonator operable at a resonant frequency with a first quality factor, and wherein a change in the external magnetic field causes the first quality factor to change to a second quality factor.

According to another example embodiment, the resonator is operable at the resonant frequency with the first quality factor in the absence of the external magnetic field, and wherein the external magnetic field causes the change to the second quality factor. In one example embodiment, the resonator is configured as a single port device, and the second quality factor is smaller than the first quality factor. In one example embodiment, the resonator is configured to include an input port and an exit port, and the second quality factor is larger than the first quality factor. In one example embodiment, the resonator is a ring or a disc resonator. In one example embodiment, the resonator is configured as a racetrack or an oval-shaped resonator.

In one example embodiment, a detection sensitivity of the magnetometer to the external magnetic field is tunable based on one or more of: a Verdet constant of the polymer-based MO material, dimensions of the core, dimensions of the cladding or a quality factor of a resonator that is formed as part of the magnetometer. In one example embodiment, the external magnetic field is operable to rotate polarization of the polarized light through interactions with the polymer-based MO material and induce a loss in a detected output signal.

Various information and data processing operations described herein are described in the general context of methods or processes, which may be implemented in one embodiment by a computer program product, embodied in a computer-readable medium, including computer-executable instructions, such as program code, executed by computers in networked environments. A computer-readable medium may include removable and non-removable storage devices including, but not limited to, Read Only Memory (ROM), Random Access Memory (RAM), compact discs (CDs), digital versatile discs (DVD), etc. Therefore, the computer-readable media that is described in the present application comprises non-transitory storage media. Generally, program modules may include routines, programs, objects, components, data structures, etc. that perform particular tasks or implement particular abstract data types. Computer-executable instructions, associated data structures, and program modules represent examples of program code for executing steps of the methods disclosed herein. The particular sequence of such executable instructions or associated data structures represents examples of corresponding acts for implementing the functions described in such steps or processes.

The foregoing description of embodiments has been presented for purposes of illustration and description. The foregoing description is not intended to be exhaustive or to limit embodiments of the present invention to the precise form disclosed, and modifications and variations are possible in light of the above teachings or may be acquired from practice of various embodiments. The embodiments discussed herein were chosen and described in order to explain the principles and the nature of various embodiments and its practical application to enable one skilled in the art to utilize the present invention in various embodiments and with various modifications as are suited to the particular use contemplated. While operations are depicted in the drawings in a particular order, this should not be understood as requiring that such operations be performed in the particular order shown or in sequential order, or that all illustrated operations be performed, to achieve desirable results. The features of the embodiments described herein may be combined in all possible combinations of methods, apparatus, modules, and systems.

1. A magnetometer, comprising:
a core comprising a photonic material, wherein the core is configured to receive polarized light and maintain propagation of the polarized light that traverses therethrough;
a cladding that comprises a polymer-based magneto-optic (MO) material, wherein the polymer-based MO material is in contact with the core and surrounds at least part of the core, the core and the cladding configured to allow at least a portion of the polarized light to enter the cladding to interact with the polymer-based MO material in presence of an external magnetic field, and wherein measurements of polarization state of light after interaction with the polymer-based magneto-optic (MO) material enable a determination of a strength of the magnetic field.

2. The magnetometer of claim 1, wherein the core comprises a silicon-based material.

3. The magnetometer of claim 2, wherein the silicon-based material comprises silicon nitride (Si₃N₄).

4. The magnetometer of claim 1, wherein the polymer-based MO material has a Verdet constant in the range 2×10³ and 2×10⁶.

5. The magnetometer of claim 1, wherein the magnetometer is implemented as part of an integrated photonic chip.

6. The magnetometer of claim 1, wherein the magnetometer is configured as a resonator operable at a resonant frequency with a first quality factor, and wherein a change in the external magnetic field causes the first quality factor to change to a second quality factor.

7. The magnetometer of claim 6, wherein the resonator is operable at the resonant frequency with the first quality factor in the absence of the external magnetic field, and wherein the external magnetic field causes the change to the second quality factor.

8. The magnetometer of claim 6, wherein the resonator is configured as a single port device, and the second quality factor is smaller than the first quality factor.

9. The magnetometer of claim 6, wherein the resonator is configured to include an input port and an exit port, and the second quality factor is larger than the first quality factor.

10. The magnetometer of claim 6, wherein the resonator is a ring or a disc resonator.

11. The magnetometer of claim 6, wherein the resonator is configured as a racetrack or an oval-shaped resonator.

12. The magnetometer of claim 1, wherein a detection sensitivity of the magnetometer to the external magnetic field is tunable based on one or more of: a Verdet constant of the polymer-based MO material, dimensions of the core, dimensions of the cladding, or a quality factor of a resonator that is formed as part of the magnetometer.

13. The magnetometer of claim 1, wherein the external magnetic field is operable to rotate polarization of the polarized light through interactions with the polymer-based MO material and induce a loss in a detected output signal.

14. A method for measuring a magnetic field using a magnetometer, the method comprising:
receiving polarized light at the magnetometer, wherein the magnetometer includes an optical resonator that is operable at a resonant frequency or wavelength in the absence of an external magnetic field, the magnetometer comprising:
a core comprising a photonic material, wherein the core is configured to receive the polarized light and maintain propagation of the polarized light that traverses therethrough; and
a cladding that comprises a polymer-based magneto-optic (MO) material, wherein the polymer-based MO material is in contact with the core and surrounds at least part of the core, the core and the cladding configured to allow at least a portion of the polarized light to enter the cladding to interact with the polymer-based MO material;
positioning an operating wavelength of the resonator on resonance to obtain a first output power value from the optical resonator;
exposing the magnetometer to the external magnetic field;
measuring light that is output from the optical resonator in the presence of the external magnetic field to obtain a second output power value; and
determining a strength of the external magnetic field based on differing values of the first output power value and the second output power value.

15. The method of claim 14, wherein the strength of the external magnetic field is proportional to a difference in the first output power value and the second output power value.

16. The method of claim 14, wherein positioning the operating wavelength of the resonator on resonance is associated with obtaining a measured output power value, from the optical resonator in the absence of the external magnetic field, that is minimized.

17. The method of claim 14, wherein the optical resonator is one of a ring or a disc resonator.

18. The method of claim 14, wherein the optical resonator is non-circularly symmetric, and the method further comprises:
changing a relative orientation of the optical resonator and the external magnetic field;
measuring light that is output from the optical resonator in the presence of the external magnetic field to obtain a third output power value; and
determining a direction of the external magnetic field based on at least the second and the third output power values.

19. The method of claim 18, wherein the direction of the external magnetic field is determined as function of an angular position of the optical resonator in the presence of the external magnetic field.

20. The method of claim 14, wherein the magnetometer is part of an integrated photonic chip.

21. The method of claim 14, wherein a detection sensitivity of the magnetometer to the external magnetic field is based on one or more of: a Verdet constant of the polymer-based MO material, dimensions of the core, dimensions of the cladding or a quality factor of the optical.
